(19) United States
(12) Patent Application Publication
(10) Pub. No.: US 2007/0128887 A1
(43) Pub. Date: Jun. 7, 2007

(54) Spin-on glass passivation process

(75) Inventors: Lee-Jen Chen, Taipei (TW); Chin-Ta Su, Yunlin (TW)

Correspondence Address: BAKER & MCKENZIE LLP;PATENT DEPARTMENT, 2001 ROSS AVENUE, SUITE 2300, DALLAS, TX, 75201, US

(73) Assignee: Macronix International Co., Ltd.

(21) Appl. No.: 11/295,963

(22) Filed: Dec. 7, 2005

(51) Int. Cl. H01L 21/31

(52) U.S. Cl. 438/786; 257/E21.267

(57) ABSTRACT

Integrated circuits and methods of making an integrated circuit are disclosed. The disclosed methods include providing a substrate having at least one device structure thereon; providing a first barrier layer over the substrate and the at least one device structure; providing a dielectric layer formed by a spin-on-glass process; and providing a second barrier layer over the dielectric layer, wherein the second barrier layer is a compressive layer. Integrated circuits described herein include a first barrier layer over the substrate and the at least one device structure; a dielectric layer formed by a spin-on-glass process; and a second barrier layer over the dielectric layer, wherein the second barrier layer is a compressive layer.

### BACKGROUND

1. Field of the Invention

Embodiments of the invention relate to methods for passivating spin-on-glass layers of semiconductor wafers and wafers and devices made therefrom.

2. Background of the Invention

In the prior art production of semiconductor integrated circuit devices, fine patterns of semiconductor regions, electrodes, wiring and other components are fabricated onto the semiconductor substrate by using conventional process steps, one being chemical vapor deposition (CVD). After formation of the wire pattern on the device, an interline dielectric material deposition is formed between the horizontally disposed wiring, the pattern overlaid with dielectric film forming material, and multi-layer formation processes, well-known in the art, are provided to form a multi-layered integrated semiconductor device.

Presently, advances in the semiconductor industry are characterized by the introduction of new generations of integrated circuits (ICs) having higher performance and greater functionality than that of previous generations for the purpose of obtaining rapid processing of voluminous information. These advances are often the result of reducing the size of the IC devices; that is, the advances in the integration do not rely upon the expansion of the size or dimension of the device, i.e., the chip, but can be obtained by miniaturizing and increasing the number of components fabricated in the chip and accordingly reducing the dimensions of the chips themselves. As a result, the minimum size of line and space of the wiring in the chips is on the order of submicrons and as a necessity, the wiring structure adopted in current chips is a multi-layer or multi-level wiring or metallization structure.

However, as device geometries in semiconductor wafers approach and then go beyond dimensions as small as 0.25 microns (μm), the dielectric constant of insulating material used between conductive paths, for example silicon oxide (SiO₂), becomes an increasingly significant factor in device performance. As the distance between adjacent conductive paths become smaller, the resulting capacitance, a function of the dielectric property of the insulating material divided by the distance between conductive paths, increases. This causes increased capacitive coupling, or cross-talk, between adjacent conductive paths which carry signals across the chip. The increased capacitance further results in increased power consumption for the IC and an increased RC time constant, the latter resulting in reduced signal propagation speed. In sum, the effects of miniaturization cause increased power consumption, limit achievable signal speed, and degrade noise margins used to insure proper IC device or chip operation.

Many dielectric materials have been proposed for use as dielectric film coatings in semi-conductor devices, but most of them are considered to be unsatisfactory in meeting the stringent electrical and physical requirements. Conventionally, dielectric films are applied over a patterned wiring layered structure by chemical vapor deposition (CVD) processes. Typical examples of useful inorganic dielectric materials include the already cited silicon dioxide (SiO₂), silicon nitride (Si₃N₄) and phosphosilicate glass (PSG). The preferred formation of these inorganic dielectrics by chemical vapor deposition processes leaves these inorganic dielectric layers inherently uneven because plasma based deposition processes exactly reproduce the uneven and stepped profile structure of the underlying wiring pattern.

More recently, useful organic/inorganic dielectric materials known as Spin-On-Glasses (SOGs) have generally used to provide dielectric coating layers. Layers formed from spin-on-glass materials are able to cover the underlying device structures yet do not reproduce the device features; thereby providing a more even surface. However, such materials are typically less desirable due to poor thermal stability or poor adhesion characteristics. Crack formation in spin-on-glass layers also occurs.

### SUMMARY

In one aspect, embodiments of the invention provide an integrated circuit or a portion of an integrated circuit including a substrate having at least one device structure thereon, comprising: a first barrier layer over the substrate and the at least one device structure; an insulating layer formed by a spin-on-glass process; and a second barrier layer over the dielectric layer, wherein the second barrier layer is a compressive layer.

Any composition or material suitable as a barrier layer is envisioned as the first barrier layer. Preferred barrier layers are capable of reducing or eliminating the migration of moisture or mobile ions. In some embodiments, the first barrier layer is a silicon oxynitride or silicon nitride layer. Silicon nitride or silicon oxynitride layers formed to provide a compressive force maybe particularly useful in certain embodiments. Plasma enhanced chemical vapor deposition (CVD) or other process can be used to provide suitable barrier layers.

In some embodiments the insulating layer comprises a siloxane or silicate material. In one embodiment, the insulating layer is formed by supporting a semiconductor wafer including the substrate having at least one device structure thereon and the a first barrier layer in a chamber which encloses a chamber environment; dispensing a flowable dielectric in a solvent over the first barrier layer in the chamber; covering the wafer to provide a controllable environment within and separated from the chamber environment after the step of dispensing; spinning the wafer within the controllable environment to spread and flow in the flowable dielectric; and curing the flowable dielectric to form the insulating layer.

Any composition or material suitable as a barrier layer is envisioned as the second barrier layer. The second barrier layer is formed to provide a compressive force. Some such layers are also capable of reducing or eliminating the migration of moisture or mobile ions. In some embodiments, the second barrier layer is a silicon oxynitride or silicon nitride layer. Plasma enhanced chemical vapor deposition (CVD) or other process can be used to provide suitable barrier layers.

In another aspect, embodiments of the invention provide a method of making a semiconductor device, which includes integrated circuits or portions thereof. Embodiments of the method include providing a substrate having at least one device structure thereon; providing a first barrier layer over the substrate and the at least one device structure; providing an dielectric layer formed by a spin-on-glass process; and providing a second barrier layer over the flowable dielectric layer, wherein the second barrier layer is a compressive layer.

These and other features, aspects, and embodiments of the invention are described below in the section entitled “Detailed Description.”

### BRIEF DESCRIPTION OF THE DRAWINGS

Features, aspects, and embodiments of the inventions are described in conjunction with the attached drawings, in which:

FIG. 1 illustrates an embodiment of a semiconductor device having a substrate with device or isolation features formed thereon at an intermediate stage of production;

FIG. 2 illustrates an embodiment of a semiconductor device having a barrier layer formed over the substrate and device or isolation features at an intermediate stage of production;

FIG. 3 illustrates an embodiment of a semiconductor device having an insulating spin-on glass layer formed over the barrier layer, the device or isolation structures, and the substrate at an intermediate stage of production; and;

FIG. 4 illustrates an embodiment of the invention after deposition of the compressive barrier layer over the insulating spin-on glass layer, the barrier layer, the device or isolation structures, and the substrate.

### DETAILED DESCRIPTION OF THE PREFERRED EMBODIMENTS

In the following description, all numbers disclosed herein are approximate values, regardless whether the word “about” or “approximately” is used in connection therewith. They may vary by up to 1%, 2%, 5%, or sometimes 10 to 20%. Whenever a numerical range with a lower limit, R_{L}, and an upper limit R_{U}, is disclosed, any number R falling within the range is specifically and expressly disclosed. In particular, the following numbers R within the range are specifically disclosed: R=R_{L}+k*(R_{U}-R_{L}), wherein k is a variable ranging from 1% to 100% with a 1% increment, i.e. k is 1%, 2%, 3%, $%, 5%, . . . , 50%, 51%, 52%, . . . , 95%, 96%, 97%, 98%, 99%, or 100%. Moreover, any numerical range defined by two numbers, R, as defined in the above is also specifically disclosed.

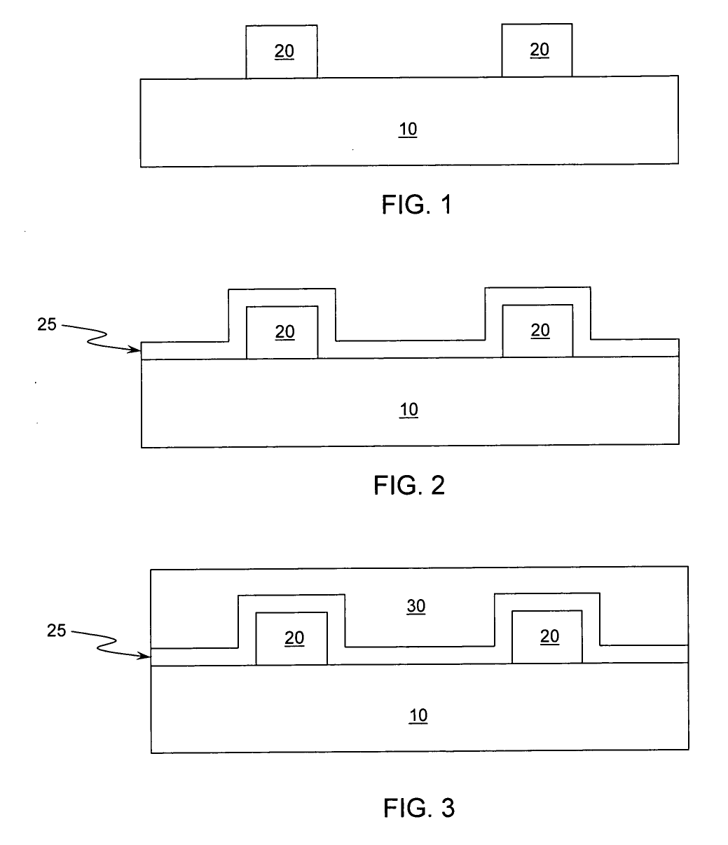

Features of some embodiments of the invention are schematically represented in FIGS. 1-4. In FIG. 1, a schematic cross sectional diagram of an integrated circuit structure is shown, wherein the substrate 10 includes device or isolation structures 20 formed thereon. Typically, the substrate 10 will have buried diffusion regions formed therein. As shown in FIG. 2, a barrier layer 25 is formed over the structures 20. The barrier layer 25 comprises silicon oxynitride (SiOₓN_{y}) or silicon nitride formed by a plasma enhanced CVD process.

In some embodiments, the barrier layer 25 is formed under conditions to provide a layer having a compressive force with respect to one or more adjacent layers. The relative compressive force can be controlled as is known in the art. Typically, the compressive force is effected by the relative interatomic distances in the materials of adjacent layers and can be affected in crystalline materials by controlling the composition and/or crystallographic orientation of the deposited layer. Some barrier layers 25 have a tensile stress of about 2×10⁸ to about 7×10⁸ dynes/cm², or about 3×10⁸ to about 6×10⁸ dynes/cm², or about 4×10⁸ to about 5×10⁸ dynes/cm². Some such barrier layers 25 substantially block the migration of moisture and mobile ions retarding or eliminating effects on the underlying metal or other semiconductor structures.

As schematically depicted in FIG. 3, after the growth of the barrier layer 25, an insulating layer 30 is provided. Typically the insulating layer 30 is provided by a spin-on-glass. One such spin-on-glass insulating layer may be formed from a flowable dielectric material. This dielectric material is laid down using a spin coat of flowable glass to fill the gaps between the device structures, such as metal lines, and to smooth out the wafer surface. The flowable glass is then cured at about 420° C. to solidify the glass. After curing, the insulating layer 30 typically has a thickness of 2000 to 5500 Angstroms. In some embodiments, the insulating layer has a refractive index of about 1.3-1.4. However, the refractive index may have any desirable value according to design parameters. Typically, gaps 0.1 μm in width and at least 1.2 μm in depth are filled by the insulating layer 30. In some embodiments, the layer 30 provides a planarity of greater that about 90% at large metal spacings (>40 μm metal spacing). Typically, spin-on glass thickness on top of large metal pad is about 1000, although any thickness can be used. After curing, some suitable layers 30 have a tensile stress ranging from about 2×10⁸ to about 7×10⁸ dynes/cm², or about 3×10⁸ to about 6×10⁸ dynes/cm², or about 4×10⁸ to about 5×10⁸ dynes/cm².

The insulating layer 40 can be formed by any currently known or later discovered process for forming spin-on-glass layers. However, in an exemplary embodiment, the spin-on-glass coating process is performed as disclosed in U.S. Pat. No. 6,004,622, incorporated herein by reference in its entirety. For convenience some details of such a process are described herein below.

Typically, providing the spin-on glass comprises a dispense step, a spread step, and a dry setting step. In the dispense step, a controlled amount of flow glass is dispensed under optimized dispense arm movement and wafer rotation speeds. A moveable cap, making an enclosed compartment around the wafer, is then used to control the ambient above the wafer during the spin-spreading step. During the spreading step, the pressure, temperature, and ambient gas composition can be controlled within the enclosed compartment. Typically, a saturated vapor ambient is kept inside the enclosed compartment to keep the glass under a highly flowable state during spreading. The centrifugal force due to the wafer rotation assists in the global smoothing of the flow glass. A high speed rotation is needed at the end of the spreading step to spin off the excess flow glass and reduce the flow glass thickness on top of large metal pads. At the last dry setting step, the ambient is exhausted to dry and set the flow glass.

The first step involves dispensing the spin-on-glass material such as commercially available siloxane polymer based materials, like Allied-Signal product numbers 512, 214and 314. This step takes less than about 2 seconds with a final spin speed of less than about 200 revolutions per minute. The final spin speed is set rapidly with an acceleration rate of about 500-2000 rpm per second. Exhaust in the spin-on-glass chamber is set at less than about 200 liters per minute (Lpm) with the cap open.

After the dispense step, the cap is closed. This process takes up to 5 seconds. The spin speed is set with a rapid deceleration of 2000-3000 rpm per second to 0 rpm. The exhaust during the cap closing step is set at up to about 200 Lpm.

After the cap is closed, the spin-on-glass material is spread and flowed in. This process takes up to about 30 seconds, preferably greater than about 20 seconds, with a relatively low spin speed of up to about 500 rpm, preferably less than about 250 rpm. The spin speed is set with an acceleration rate of about 1000-3000 rpm per second with the exhaust in the outside chamber at a value up to about 200 Lpm. During this process, the cap is closed, isolating the space inside the closed cap from the external exhaust, so that the evaporation rate of the spin-on-glass solvent is slowed down.

In the next step, the cap is opened. This step takes about up to 5 seconds with a 0 rpm spin speed. The spinning is stopped with a deceleration in a range of 2000-3000 rpm per second. The exhaust is set at a value of up to about 400 Lpm while the cap is being opened.

The final step is the spin off step which takes up to about 20 seconds. During spin off, the wafer rotates at a value between 3000-5000 rpm. The final spin speed is reached with rapid acceleration in the range of 5000-10000 rpm/s. The exhaust in the chamber is up to about 400 Lpm with the cap open.

Further engineering of the spin-on-glass can be provided using the moveable cap which allows for selective control of the environment over the integrated circuit during selected spinning steps of the process. Thus, a process might be executed as follows:

The top layer of the spin-on-glass can be modified by introducing saturated vapor solvents into the closed cap ambient, or dispensing liquid solvent directly on the wafer surface to create a graded solvent content profile across the thickness of the spin-on-glass such that the surface of the spin-on-glass has a higher solvent content than the deeper layers. Thus, very high spin off speeds can be used while preventing the spin-on-glass in deep features of the substrate from being dislodged.

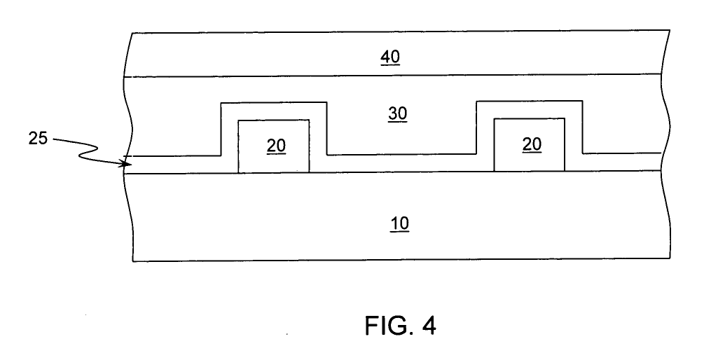

After formation of the insulating layer 30, a barrier layer 40 is provided as depicted in FIG. 4. Barrier layer 40 should be formed to provide a compressive force with respect to the underlying insulating layer 30. As described above, the compressive force is effected by the relative interatomic distances in the materials of adjacent layers and can be affected in crystalline materials by controlling the composition and/or crystallographic orientation of the deposited layer. The barrier layer 40 may have any desirable tensile strength provided it provides a compressive force with respect to the underlying layer. Typical barrier layers 40 have a tensile stress ranging from about 2×10⁸ to about 7×10⁸ dynes/cm², or 3×10⁸ to about 6×10⁸ dynes/cm², or about 4×10⁸ to about 5×10⁸ dynes/cm². Some such barrier layers 40 substantially block the migration of moisture and mobile ions retarding or eliminating effects on the underlying metal or other semiconductor structures.

The devices and processes in accordance with embodiments of the invention may offer one or more advantages such as improved passivation or improved resistance to cracking. While the invention has been described with a limited number of embodiments, these specific embodiments are not intended to limit the scope of the invention as otherwise described and claimed herein. Modification and variations from the described embodiments exist. For example, while the process and device structure have been described with respect to a generic device structure, the process and layer structures described herein may be applied to any type of device where a spin-on glass layer is formed over an integrated circuit. And while the processes are described as comprising one or more steps, it should be understood that these steps may be practiced in any order or sequence unless otherwise indicated. These steps may be combined or separated. In some embodiments, the compositions described herein may comprise other components. However, in other embodiments, any components that is not expressly recited in the composition are absent, or essentially absent, from the composition. Finally, any number disclosed herein should be construed to mean approximate, regardless of whether the word “about” or “approximate” is used in describing the number. The appended claims intend to cover all such variations and modifications as falling within the scope of the invention.

While certain embodiments of the inventions have been described above, it will be understood that the embodiments described are by way of example only. Accordingly, the inventions should not be limited based on the described embodiments. Rather, the scope of the inventions described herein should only be limited in light of the claims that follow when taken in conjunction with the above description and accompanying drawings.

What is claimed:

1. A method of making an integrated circuit, comprising:
a) providing a substrate having at least one device structure thereon;
b) providing a first barrier layer over the substrate and the at least one device structure;
c) providing an dielectric layer formed by a spin-on-glass process; and
d) providing a second barrier layer over the flowable dielectric layer, wherein the second barrier layer is a compressive layer.

2. The method according to claim 1, wherein the first barrier layer is a silicon oxynitride.

3. The method according to claim 1, wherein the first barrier layer is a compressive layer.

4. The method according to claim 1, wherein the first barrier layer is a compressive silicon oxynitride layer.

5. The method according to claim 1, wherein the first barrier layer is a compressive silicon nitride layer.

6. The method according to claim 1, wherein the first barrier layer is provided using a plasma enhanced CVD process.

7. The method according to claim 1, wherein the insulating layer comprises a siloxane or silicate material.

8. The method according to claim 1, wherein the second compressive barrier layer is a silicon oxynitride.

9. The method according to claim 1, wherein the second compressive barrier layer is a silicon nitride layer.

10. The method according to claim 1, wherein the second compressive barrier layer is provided using a plasma enhanced CVD process.

11. The method as in claim 1, wherein providing an insulating layer formed by a spin-on glass process includes: supporting the substrate having at least one device structure thereon and the a first barrier layer in a chamber which encloses a chamber environment; dispensing the flowable dielectric in a solvent over the first barrier layer in the chamber; covering the wafer to provide a controllable environment within and separated from the chamber environment after the step of dispensing; spinning the integrated circuit within the controllable environment to spread and flow in the flowable dielectric; and curing the flowable dielectric.

12. An integrated circuit including a substrate having at least one device structure thereon, comprising:
a) a first barrier layer over the substrate and the at least one device structure;
b) a dielectric layer formed by a spin-on-glass process; and
c) a second barrier layer over the dielectric layer, wherein the second barrier layer is a compressive layer.

13. The method according to claim 12, wherein the first barrier layer is a silicon oxynitride.

14. The method according to claim 12, wherein the first barrier layer is a compressive layer.

15. The method according to claim 12, wherein the first barrier layer is a compressive silicon oxynitride layer.

16. The method according to claim v, wherein the first barrier layer is a compressive silicon nitride layer.

17. The method according to claim 12, wherein the first barrier layer is provided using a plasma enhanced CVD process.

18. The method according to claim 12, wherein the insulating layer comprises a siloxane or silicate material.

19. The method according to claim 12, wherein the second compressive barrier layer is a silicon oxynitride.

20. The method according to claim 12, wherein the second compressive barrier layer is a silicon nitride layer.

21. The method according to claim 12, wherein the second compressive barrier layer is provided using a plasma enhanced CVD process.
